(19) United States
(12) Patent Application Publication
(10) Pub. No.: US 2010/0224590 A1
(43) Pub. Date: Sep. 9, 2010

(54) METHOD FOR PRODUCING MICRONEEDLE STRUCTURES EMPLOYING ONE-SIDED PROCESSING

(75) Inventors: Yehoshua Yeshurun, Haifa (IL); Meint de Boer, Enschede (NL); J.W. Berenschot, Winterswijk (NL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: NanoPass Technologies Ltd., Nes Ziona (IL)

(21) Appl. No.: 12/160,444

(22) PCT Filed: May 20, 2008
(86) PCT No.: PCT/IL08/00683

§ 371 Date: Jul. 10, 2008

Related U.S. Application Data
(60) Provisional application No. 60/939,067, filed on May 20, 2007.

(51) Int. Cl. B81C 1/00

(52) U.S. Cl. 216/41; 216/58; 216/57; 216/52

(57) ABSTRACT

A method for forming a hollow microneedle structure includes processing the front side of a wafer to form at least one microneedle projecting from a substrate and a through-bore passing through the microneedle and through a thickness of the substrate. An entire length of the through-bore is formed by a dry etching process performed from the front side of the wafer. Most preferably, upright surfaces of the microneedle structure and the through bore of the structure are formed by dry etching performed via a single mask with differing depths obtained by harnessing aspect ratio limitations of the dry etching process.

### FIELD AND BACKGROUND OF THE INVENTION

The present invention relates to methods for producing microneedle structures and, in particular, it concerns production methods in which the microneedle structure and a through-bore are formed by one-sided processing of a wafer.

In MEMS technology, several processing techniques are available for use in fabricating devices, each with its own particular characteristics, advantages and disadvantages. Of particular importance in the context of the present invention are two groups of processing techniques referred to generically as “wet etching processes” and “dry etching processes.” In the dry etching processes category, particular reference will be made to Deep Reactive Ion Etching (DRIE).

In wet etching processes, a wafer with a suitable mask is processed by immersion in an etchant so as to selectively etch away parts of the wafer to form a desired structure, either isotropically or anisotropically. Wet etching techniques are limited as to what structures they can produce and, most notably, cannot be used for forming high aspect ratio structures, i.e., a height or depth of the structure are large compared to the width, or where near-vertical surfaces are required.

In order to manufacture a high aspect ratio structure or hole, DRIE techniques are used. For example, in the field of hollow microneedles, a hole with a high aspect ratio hole (greater then 10:1) is often required. Such holes cannot be formed using conventional wet etching techniques, so a DRIE technique is used instead.

DRIE is typically implemented either using a process known as “the Bosch process” (including repeated deposition of a passivation layer) or under cryogenic conditions, thereby inhibiting isotropic etching and limiting the etching process to the direction of direct ion bombardment. This process can form structures perpendicular to a wafer surface, for example a silicon wafer, with high aspect ratio such as holes and wall structures with substantially any desired cross sectional shape.

In the field of microneedle fabrication, U.S. Pat. No. 6,533,949 to Yeshurun et al. (hereafter “the '949 patent”), which is hereby incorporated by reference in its entirety, discloses fabrication techniques for hollow microneedles in which DRIE processes are used to form upright surfaces of the microneedles and a through-bore while wet etching techniques are used to form an oblique surface, thereby defining various hollow microneedle structures. The structures described therein have been found highly advantageous, combining robustness and sharpness, as well as providing a geometry for a fluid flow bore which does not become blocked during penetration of the skin. The production technique described, however, relies upon forming aligned bores from the front side and back side of the wafer intersecting to form the fluid flow bores passing through the substrate.

In order to ensure formation of a continuous through-bore, i.e., a bore passing through the entire thickness of the substrate, the '949 patent requires dry etching processes on both the front side and back side of the wafer. Highly precise alignment must be achieved between the front side and back side masks in order to ensure that the bores meet. This alignment is difficult to achieve, requiring time consuming and laborious alignment procedures and reducing production yield. Furthermore, the manipulation of the wafer from both sides requires cautious handling and may result in unexpected breakage of the thin wafer.

It would therefore be highly advantageous to provide a structure and corresponding production method which would achieve the advantageous properties of the structures taught by the '949 patent and variants or modifications thereof through a production method which would only require one-sided processing of a wafer.

### SUMMARY OF THE INVENTION

The present invention is a method for forming a hollow microneedle structure.

According to the teachings of the present invention there is provided, a method for forming a hollow microneedle structure comprising the steps of: (a) providing a wafer having a front side and a back side; and (b) processing the front side to form at least one microneedle projecting from a substrate and a through-bore passing through the microneedle and through a thickness of the substrate, wherein an entire length of the through-bore is formed by a dry etching process performed from the front side of the wafer.

According to a further feature of the present invention, an external shape of the microneedle is formed by at least two intersecting surfaces, at least a first of the surfaces being formed by a dry etching process and at least a second of the surfaces being formed by a wet etching process.

According to a further feature of the present invention, the first surface and at least part of the through-bore are formed concurrently.

According to a further feature of the present invention, the first surface and the entire length of the through-bore are formed by dry etching performed via a single mask, and wherein a width of an etched channel in the single mask and conditions of the dry etching process are chosen such that a depth of etching to form the first surface is limited by a maximum aspect ratio of the dry etching process.

According to a further feature of the present invention, the through-bore intersects the second surface.

According to a further feature of the present invention, an external shape of the microneedle includes at least one substantially upright surface formed by dry etching, the substantially upright surface and the entire length of the through-bore being formed by dry etching performed via a single mask, and wherein a width of an etched channel in the single mask and conditions of the dry etching process are chosen such that a depth of etching to form the first surface is limited by a maximum aspect ratio of the dry etching process.

According to a further feature of the present invention, the wafer is a silicon wafer.

According to a further feature of the present invention, a plurality of the microneedles with the through-bores are formed in distinct regions of the wafer for subdivision into chips, and wherein the method further comprises forming, concurrently with formation of at least part of the through-bore, dicing channels on the front side extending along dicing lines between the distinct regions.

According to a further feature of the present invention, the dicing channels are formed so as to traverse an entire thickness of the substrate, thereby separating the distinct regions into chips.

According to a further feature of the present invention, a dicing process is performed to sever a remaining thickness of the wafer after formation of the dicing channels so as to separate the distinct regions into chips.

There is also provided according to the teachings of the present invention, a method for forming a hollow microneedle structure comprising the steps of: (a) providing a wafer having a front side and a back side; and (b) processing the front side to form: (i) at least one microneedle projecting from a substrate, an external shape of the microneedle including at least one substantially upright surface, and (ii) a through-bore passing through the microneedle and through a thickness of the substrate, wherein an entire length of the through-bore and the substantially upright surface of the microneedle are formed by a dry etching process performed via a single mask, and wherein a width of an etched channel in the single mask and conditions of the dry etching process are chosen such that a depth of etching to form the first surface is limited by a maximum aspect ratio of the dry etching process.

### BRIEF DESCRIPTION OF THE DRAWINGS

The invention is herein described, by way of example only, with reference to the accompanying drawings, wherein:

FIGS. 1A-1C are an upper isometric view, an upper partially-cut-away isometric view and a lower partially-cut-away isometric view, respectively, of a first stage during a preferred implementation of a method for production of a microneedle structure according to the teachings of the present invention, showing a wafer with a photoresist mask;

FIGS. 2A-2D are an upper isometric view, an upper partially-cut-away isometric view, a partial enlarged view of the cut-away view and a lower partially-cut-away isometric view, respectively, of a second stage during the method of FIGS. 1A-1C, after a dry etching process;

FIGS. 3A-3C are an upper isometric view, an upper partially-cut-away isometric view and a lower partially-cut-away isometric view, respectively, of a third stage during the method of FIGS. 1A-1C, after application of a protective silicon nitride layer;

FIGS. 4A-4C are an upper isometric view, an upper partially-cut-away isometric view and a lower partially-cut-away isometric view, respectively, of a fourth stage during the method of FIGS. 1A-1C, after removal of the silicon nitride layer from the front side of the wafer;

FIGS. 5A-5C are an upper isometric view, an upper partially-cut-away isometric view and a lower partially-cut-away isometric view, respectively, of a fifth stage during the method of FIGS. 1A-1C, after a wet etching process;

FIGS. 6A-6C are an upper isometric view, an upper partially-cut-away isometric view and a lower partially-cut-away isometric view, respectively, of a sixth stage during the method of FIGS. 1A-1C, after stripping of the silicon nitride layer; and

FIGS. 7A-7C are an upper isometric view, an upper partially-cut-away isometric view and a lower partially-cut-away isometric view, respectively, of a final form of the microneedle structure produced by the method of FIGS. 1A-1C, after an oxidation process to form a protective coating of silicon oxide.

### DESCRIPTION OF THE PREFERRED EMBODIMENTS

The present invention is a method for forming a hollow microneedle structure and correspond microneedle structures.

The principles and operation of production methods and structures according to the present invention may be better understood with reference to the drawings and the accompanying description.

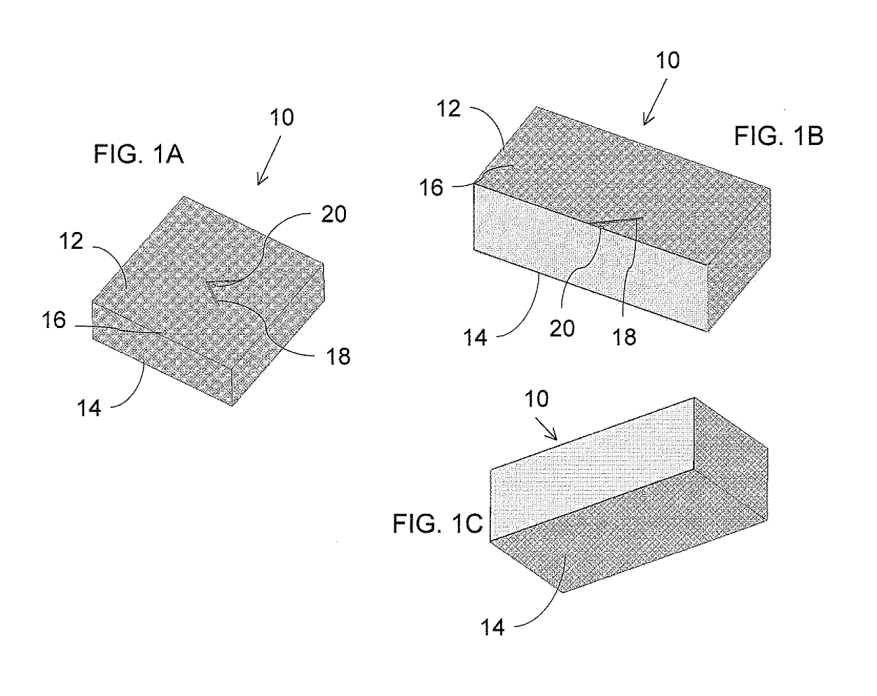

Referring now to the drawings, FIGS. 1A-7C illustrate schematically various stages during a method for forming a hollow microneedle structure. Generally speaking, the method includes providing a wafer having a front side and a back side, and processing the front side to form at least one microneedle projecting from a substrate and a through-bore passing through the microneedle and through a thickness of the substrate. It is a particular feature of the present invention that an entire length of the through-bore is formed by a dry etching process performed from the front side of the wafer. This enables the entire microneedle structure to be produced by front side processing alone, thereby avoiding the disadvantages associated with the two-sided processing techniques of the '949 patent, as detailed above.

According to a further preferred aspect of the present invention, upright surfaces of the microneedle structure and the through bore of the structure are formed by dry etching performed via a single mask. The differing depths required for the different features are achieved by harnessing aspect ratio limitations of the dry etching process. By suitable choices of dimensions for features in the mask used, differential depths of features in excess of 20%, and even up to more than 2:1 depth ratios, can be achieved. These and other features of the present invention will be better understood with reference to the following detailed description.

Before addressing the features of the present invention in more detail, it will be helpful to define certain terminology as used herein in the description and claims. The term “MEMS” is used herein loosely to refer to the field of technology and corresponding production techniques for producing mechanical structures with dimensions in the micron range up to several hundred microns. In most cases, the microneedle structures of the present invention do not include electronic components and could thus be more accurately referred to as Micro-Mechanical Systems “MMS”. However, for the purpose of readability, the more standard “MEMS” terminology will be maintained.

The term “wafer” is used to refer to a block of material from which the microneedle structures of the present invention are produced, primarily by etching techniques. The invention applies primarily to semiconductor wafers, and most preferably to silicon wafers. It should be noted that the structures of the present invention may be referred to as “formed from silicon” despite a surface layer of silicon dioxide which is always present under ambient conditions, and which may be further developed in order to impart desired mechanical or other properties to the final structure, all as is well known in the art. Similarly, the invention encompasses structures made from other materials and/or coated with other coatings or surface layers to impart desired properties.

The term “etching” is used to refer to any process step which selectively removes material from the wafer. “Wet etching” is used to refer to processes in which surfaces of the wafer are selectively covered by a mask and the wafer is then exposed in its entirety, or at least over an entire side, to a chemical etchant, whether by immersion in a bath, by spray application or by any other type of exposure. “Dry etching” is used to refer to processes in which an active species effective to cause etching is applied directionally to the wafer surface, as exemplified by reactive ion etching (RIE). The term “deep reactive ion etching” (DRIB) is used generically to refer to any implementation of RIE or a similar process which is effective to form high aspect ratio features and/or near vertical surfaces. Examples of DRIE include, but are not limited to, cryogenic-DRIB and Bosch-process DRIB. Practical implementation details for all of the various etching techniques referred to herein are, per se, well known to those ordinarily skilled in the art, and will not be addressed here in detail.

In cases of selective etching, the selectivity is typically provided by a “mask” which is patterned by photolithography, all as is well known in the art. In the following description and claims, reference will be made to certain operations which are performed using a “single mask”. For the purpose of the description and claims, the number of masks used in a given MEMS process is determined by the number of distinct photolithography exposures used during the process to generate a mask. A single mask thus defined may be used in a number of different process steps. Similarly, a re-exposure to renew a previously generated mask of the same pattern is not counted as a separate mask.

The term “substrate” is used to refer to the remaining thickness of the substrate which provides an underlying roughly planar surface from which the final microneedles project. Commonly, a single wafer may be processed to fabricate a plurality of microneedle structures at the same time. In such cases, the term “chip” refers to a defined sub-region of the wafer (or substrate) which is to be severed or otherwise separated along “dicing lines” to form a microneedle structure. Unless otherwise specified, the term “dicing” refers to any technique which can be employed to separate a wafer into chips along dicing lines. The term “sever” is used to refer specifically to a cutting operation performed by a saw or other mechanical cutting device.

The term “microneedle” is used herein to refer to a solid structure protruding from a substrate to a height of between 30 microns and 1000 microns, and most preferably between 250 microns and 800 microns. A microneedle is referred to as “hollow” if it has a bore passing through it to allow supplying or sampling of fluid through the bore. The hole or bore is referred to as a “through-bore” if it passes through to the back side of the substrate. The bore can have any cross-sectional shape.

When reference is made to the “external shape” of the microneedle, this refers to the external surfaces making up the three dimensional shape of the microneedle without reference to the internal surfaces of the bore. Surfaces or directions are referred to as “upright” if they are generally perpendicular to the surface of the wafer or the substrate. For convenience of reference, use may be made of “vertical”, “up”, “down”, “height” or the like to refer to directions or dimensions generally perpendicular to the initial plane of the surface of the wafer, and “horizontal”, “width” or the like to refer to directions or dimensions generally parallel to the initial plane of the surface of the wafer. The word “oblique” is used to refer to a surface which is significantly inclined both to the horizontal and vertical, and is defined quantitatively (unless specified otherwise) as a surface forming an angle of between 20 degrees and 70 degrees to the upright.

The term “aspect ratio” refers to the ratio of the height to width of a given structure or feature. Particularly in relation to bores and troughs, the aspect ratio corresponds to the ratio of the maximum depth of the bore or trough to the diameter of a round bore or to the minimum side-to-side dimension of a trough.

The term “concurrently” refers to two operations which occur during coincident or overlapping time periods, either where one begins and ends during the duration of the other, or where a later one starts before the completion of the other. The term “subsequently” refers to a later operation which occurs after completion of the earlier operation. It should be noted that any reference in the description and claims to a plurality of operations or steps should not be taken to define any particular order in which the operations or steps are to be performed unless such temporal relation is explicitly stated.

Turning now to the features of the present invention in more detail, FIGS. 1A-7C illustrate one non-limiting but particularly preferred implementation of the present invention. A wide range of alternative implementations based upon the teachings of the present invention will be clear to a person having ordinary skill in the art.

Turning first to FIGS. 1A-1C, this illustrates the result of initial processing stages through to completion of a mask formed by photolithography. The process preferably starts with a wafer 10 of semiconductor material, most preferably silicon. The thickness of the wafer is chosen according to the height of the desired microneedles plus the thickness of remaining substrate required to provide the required mechanical strength. In one exemplary implementation, for forming microneedles of about 450 microns height, a wafer of 650 microns thickness may be used. The wafer is preferably polished with a <100> front side 12 and parallel back side 14. Wafer 10 need only be polished to a high quality planar surface on the front side. In certain preferred examples, p-type doped silicon with resistivity of 10-15 ohm centimeter may be used. Wafer 10 may be cleaned by standard procedures prior to processing if necessary.

The wafer is then coated, preferably on both sides, with a thick protective layer 16 of “resist”. At least for the front side, the protective layer is “photo-resist”, such as SU-8, which enables formation of a mask by photolithographic techniques. The thickness of the photo-resist layer is chosen so as to withstand dry etch processing sufficient to form a through-bore through the entire thickness of the substrate. For SU-8, which has etch rates typically in the range of 35-60 nm/min, a coating thickness in the range of 5-10 microns is typically sufficient.

The back side protective layer may be formed from the same photo-resist as used on the front side, or may be a protection layer of any other “resist” material. The back side protection layer helps to ensure a uniform etching along the entire depth of the through-bore, and also facilitates proper wafer temperature control during the etching process.

Photolithographic patterning of the front side layer is then performed to define a mask with a number of openings for each microneedle to be formed, as will now be detailed. For each microneedle to be formed, a narrow trench 18 is defined corresponding to the position of the upright surfaces of the desired microneedle form. The geometric arrangement of the upright surfaces of the final microneedle may be chosen according to any of the forms shown in the '949 patent, or variants thereof, including one curved surface or two or more straight or curved surfaces.

According to this particularly preferred, but non-limiting, implementation, the width of the trench is chosen in coordination with the maximum aspect ratio which is generated by the conditions of dry etching to be used so that the etching process will limit itself to substantially the desired depth of trench, corresponding to the desired height of the final microneedle structure. Thus, in the example of a 450 micron microneedle, a trench width of between about 10 microns and about 20 microns is typically used. This corresponds to an aspect ratio of between about 45 to about 22.5. It is known that any given working conditions for a dry etch process, such as DRIE, define a maximum limit for the aspect ratio which can be achieved. In particular, amongst other parameters, the energy of ion bombardment defines the mean free path of the ions, which is a major factor in defining the maximum aspect ratio limit. In practice, the exact width required for trench 18 may be determined experimentally for given processing parameters based on a trial run in which a test wafer with trenches of various different widths is etched and the actual etching depths measured, for example, by cutting (dicing) the test wafer across the trenches and using scanning electron microscopy (SEM), or by ultrasonic surface wave techniques normally used for measuring crack depth in structural materials. In order to ensure representative results in the trial run, the macro loading, i.e., the total exposed area of silicon being etched, should be similar to that of the final device mask, all as will be clear to one ordinarily skilled in the art.

In addition to trench 18, an opening 20 in the mask is formed for each microneedle to be formed corresponding to the through-bore to be etched through the microneedle and substrate. In order to ensure completion of the through-bore etched through the entire thickness of wafer 10, the minimum side-to-side dimension of opening 20 is significantly greater than the width of trench 18, and preferably at least twice that width. In the preferred but non-limiting example described herein, opening 20 may be implemented as a round hole of diameter roughly 50 microns. This gives an aspect ratio of 650/50 or 13. It should be noted that different sizes and different shapes of bore may also be used.

Although illustrated here schematically and for simplicity of presentation as a single microneedle on a wafer, it should be noted that particularly preferred implementations of the present invention provide a plurality of microneedles formed in distinct regions of the wafer for subdivision into chips. In such implementations, etching may optionally be performed along dicing lines between the distinct regions, either to form an etched channel to facilitate subsequent mechanical dicing of the wafer into chips, or through the full depth of the wafer to achieve dicing without mechanical severing. Here too, the depth of a dicing channel to be etched may be limited by patterning a correspondingly narrow trench in the mask.

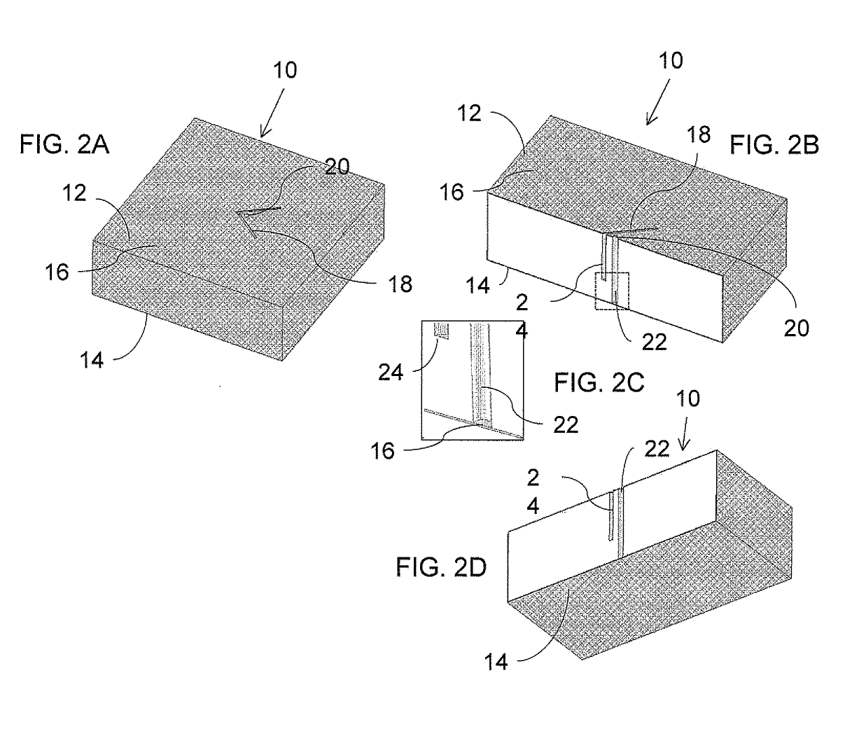

Turning now to FIGS. 2A-2D, the process then continues with front side dry etching, typically implemented as DRIE using a standard Bosch process. The etching process is continued until the main through-bore 22 of the microneedles is completed, having uniformly reached the inner surface of the back side protective coating. As described above, during this process, trench 18 results in a limited depth slot 24 corresponding to the desired height of the microneedle. The resulting structure is shown most clearly in the enlarged view of FIG. 2C. Dicing lines/trenches, if present, also result in dicing channels of the corresponding planned depth.

The protective layer and any fluorocarbon resulting from the etching process are then stripped by conventional techniques. For example, piranha solution removal of SU-8 photo-resist followed by removal of fluorocarbon by heating in an oxygen-rich atmosphere in a furnace to about 800° C. Removal of fluorocarbon is desirable in order to allow effective adhesion of a nitride layer to the slots in the next step. The wafer is then preferably cleaned and put through a hydrogen fluoride dip to remove any surface contamination prior to performing the next step.

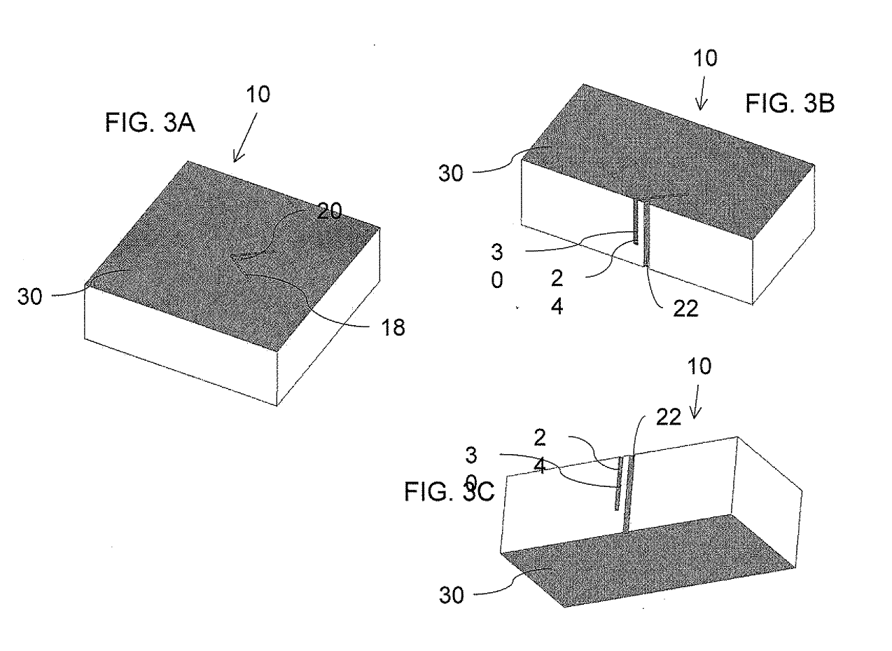

Low pressure chemical vapor deposition (LPCVD) is then used to form a low stress layer of silicon nitride in a conformal step coverage with thickness of 0.5-1.0 micron. The result of this process is illustrated in FIGS. 3A-3C, with the nitride layer designated 30. The use of a low-stress layer (tensile or compressive stress preferably less than 0.5 GPa, and typically around 0.3 GPa) is helpful to avoid cracking of the thick nitride layer during subsequent KOH etching.

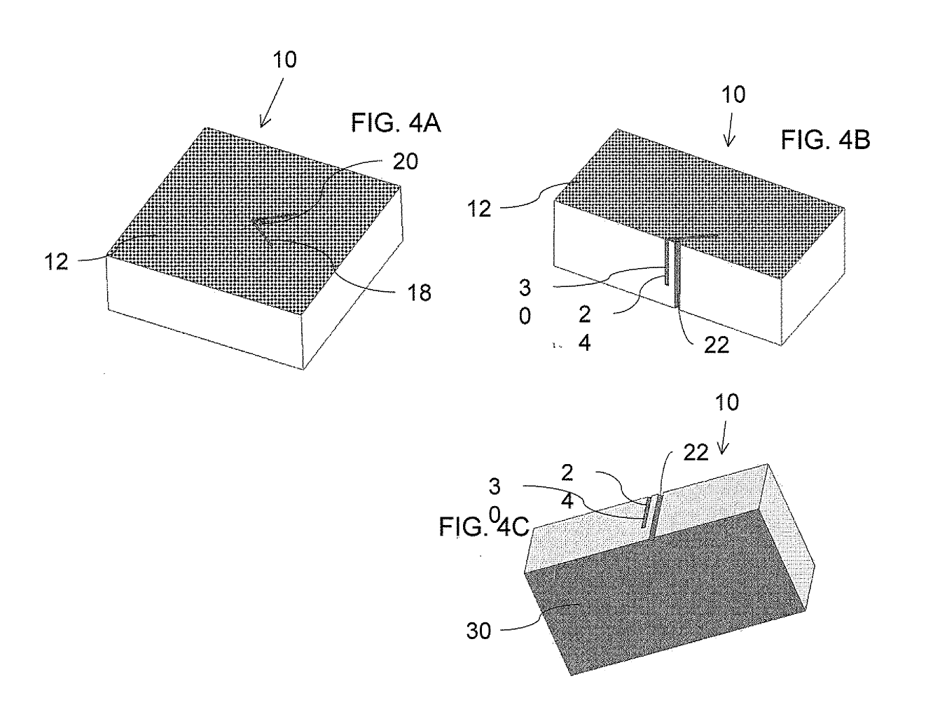

The nitride layer 30 is then selectively removed from front side 12 by a mask-less stripping process. This is most preferably achieved by a DRIB process performed without ion bombardment and with a high selectivity for silicon nitride. Examples of suitable etchants for this process may be found, for example, in the article “Selective etching of silicon nitride using remote plasmas of CF4 and SF6”, J. Vac. Sci. Technol. A, Vol. 7, No. 3, May/June 1989, pgs 686-690. The wafer is then cleaned and put through a hydrogen fluoride dip. The resulting structure is illustrated in FIGS. 4A-4C, with the inner surfaces of the bore 22 and slots 24, and back side 14 coated with a silicon nitride layer 30, while the silicon surface of front side 12 is exposed.

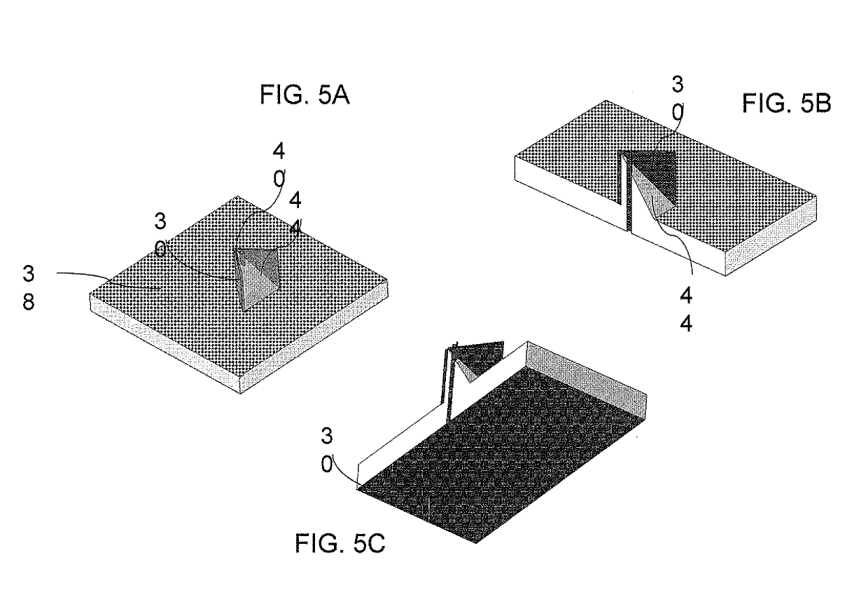

Then, after cleaning and an HF dip, wafer 10 is subjected to wet etching by KOH, stopping when etched depth corresponds to the desired needle height. The resulting structure is shown in FIGS. 5A-5C.

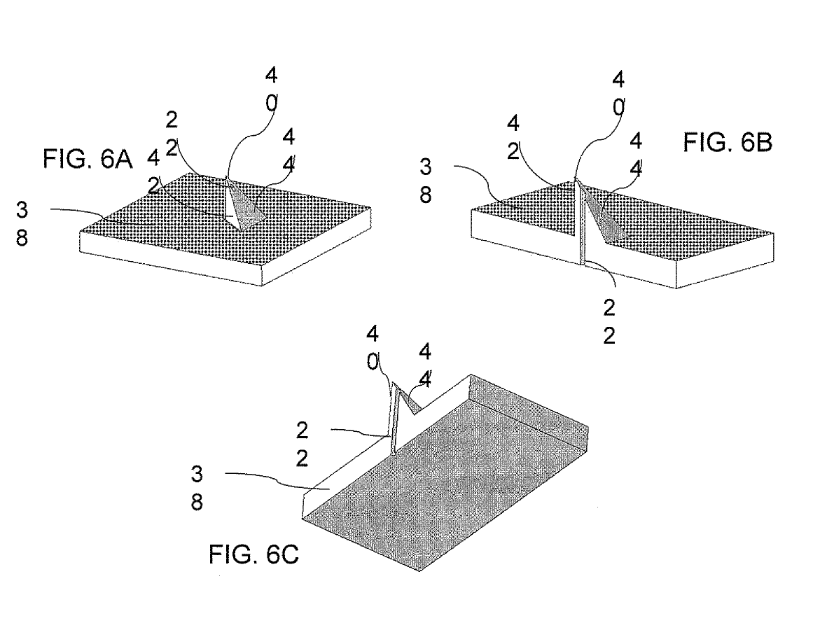

The silicon nitride is then stripped, for example, in 50% HF solution to reveal the final geometrical form of the hollow microneedle(s) 40 projecting from an underlying substrate 38 as illustrated in FIGS. 6A-6C. As mentioned above, the preferred form of the microneedles 40 produced by the method of the present invention is similar to those of the '949 patent. Thus, the external shape of the resulting microneedles preferably includes a number of upright surfaces 42 (corresponding to an internal surface of slot 24 formed by the dry etching process) and at least one oblique surface 44 (formed by the wet etching process) which intersects the upright surfaces to define a cutting edge, and optionally also a point, of the microneedle. The through-bore 22 preferably intersects the oblique surface 44, as shown.

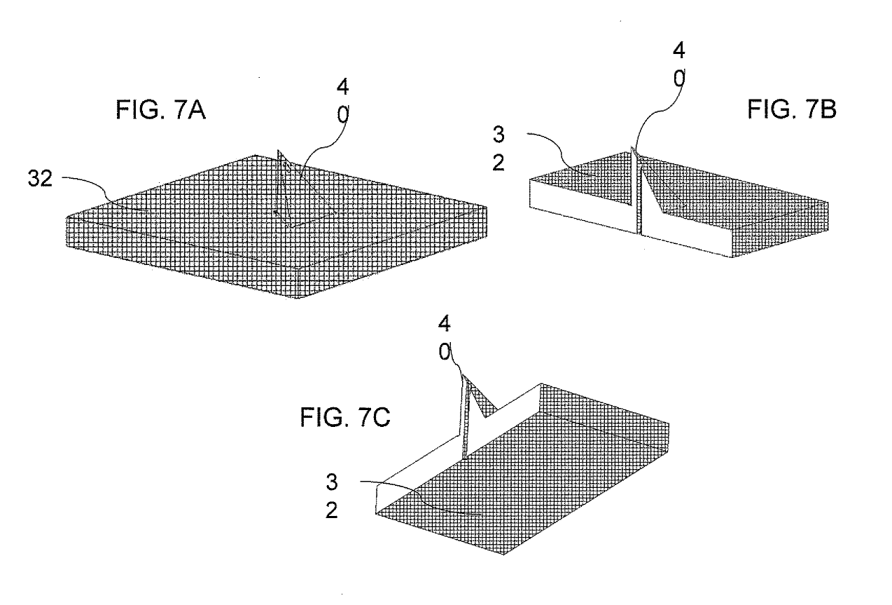

Most preferably, the structure is then post-treated by oxidation to generate a silicon oxide surface layer 32 (FIGS. 7A-7C). The oxidation conditions are preferably chosen so as to avoid build up of stress in the silicon. Finally, dicing is completed by severing the chips where necessary.

Although described herein with reference to an implementation using a single mask, it should be noted that alternative implementations employing two or more masks, all on the front side of the wafer, also fall within the broad scope of the present invention. The use of plural masks releases the requirement for aspect-ratio-limited depth of etching, thereby allowing the use of wider, lower-precision trenches 18. The use of plural masks all on the front side of the wafer presents much less problem for precision alignment due to the readily visible features created by processing through the first (or previous) mask before the second (or subsequent) mask is applied.

It will be appreciated that the above descriptions are intended only to serve as examples, and that many other embodiments are possible within the scope of the present invention as defined in the appended claims.

What is claimed is:

1. A method for forming a hollow microneedle structure comprising the steps of:
(a) providing a wafer having a front side and a back side; and
(b) processing the front side to form at least one microneedle projecting from a substrate and a through-bore passing through said microneedle and through a thickness of said substrate,
wherein an entire length of said through-bore is formed by a dry etching process performed from the front side of the wafer.

2. The method of claim 1, wherein an external shape of said microneedle is formed by at least two intersecting surfaces, at least a first of said surfaces being formed by a dry etching process and at least a second of said surfaces being formed by a wet etching process.

3. The method of claim 2, wherein said first surface and at least part of said through-bore are formed concurrently.

4. The method of claim 2, wherein said first surface and the entire length of said through-bore are formed by dry etching performed via a single mask, and wherein a width of an etched channel in said single mask and conditions of said dry etching process are chosen such that a depth of etching to form said first surface is limited by a maximum aspect ratio of said dry etching process.

5. The method of claim 2, wherein said through-bore intersects said second surface.

6. The method of claim 1, wherein an external shape of said microneedle includes at least one substantially upright surface formed by dry etching, said substantially upright surface and the entire length of said through-bore being formed by dry etching performed via a single mask, and wherein a width of an etched channel in said single mask and conditions of said dry etching process are chosen such that a depth of etching to form said first surface is limited by a maximum aspect ratio of said dry etching process.

7. The method of claim 1, wherein said wafer is a silicon wafer.

8. The method of claim 1, wherein a plurality of said microneedles with said through-bores are formed in distinct regions of said wafer for subdivision into chips, and wherein the method further comprises forming, concurrently with formation of at least part of said through-bore, dicing channels on said front side extending along dicing lines between said distinct regions.

9. The method of claim 8, wherein said dicing channels are formed so as to traverse an entire thickness of said substrate, thereby separating said distinct regions into chips.

10. The method of claim 8, further comprising performing a dicing process to sever a remaining thickness of said wafer after formation of said dicing channels so as to separate said distinct regions into chips.

11. A method for forming a hollow microneedle structure comprising the steps of:
(a) providing a wafer having a front side and a back side; and
(b) processing the front side to form:
(i) at least one microneedle projecting from a substrate, an external shape of said microneedle including at least one substantially upright surface, and
(ii) a through-bore passing through said microneedle and through a thickness of said substrate,
wherein an entire length of said through-bore and said substantially upright surface of said microneedle are formed by a dry etching process performed via a single mask, and wherein a width of an etched channel in said single mask and conditions of said dry etching process are chosen such that a depth of etching to form said first surface is limited by a maximum aspect ratio of said dry etching process.
